(19) United States
(12) Patent Application Publication
(10) Pub. No.: US 2021/0116480 A1
(43) Pub. Date: Apr. 22, 2021

(54) CIRCUIT AND METHOD FOR DETECTING INPUT VOLTAGE RISING SPEED

(71) Applicant: Shenzhen China Star Optoelectronics Semiconductor Display Technology Co., Ltd., Shenzhen (CN)

(72) Inventor: Xianming Zhang, Shenzhen (CN)

(21) Appl. No.: 16/321,828

(22) PCT Filed: Sep. 29, 2018
(86) PCT No.: PCT/CN2018/108582

§ 371 Date: Jan. 29, 2019

(30) Foreign Application Priority Data
Jul. 18, 2018 (CN) 201810791970.6

(51) Int. Cl. G01R 19/12; G01R 31/40

(52) U.S. Cl. CPC G01R 19/12; G01R 31/40

(57) ABSTRACT

The invention provides a circuit and a method for detecting the rising speed of an input voltage. The circuit includes: a voltage dividing circuit provides a first voltage; a charging circuit having a capacitor, a switch, and a current source to provide a second voltage; a comparison result of a first comparator output is used to control the switch; and a second comparator outputs the first result, a third comparator outputs a second result; a fourth comparator outputs a third result; and a logic determiner for receiving the first result, second result and third result, and determining whether a logical determination is needed according to third result; when needed, determining the input voltage according to the preset logic, the first result, and the second result, and outputting a fourth result. The invention can detect the rising speed of the input voltage inside a power management circuit.

### BACKGROUND OF THE INVENTION

### 1. Field of the Invention

The present invention relates to the field of display, and in particular to a circuit and method for detecting input voltage rising speed.

### 2. The Related Arts

With the development of display technology, the panel display devices such as liquid crystal displays (LCDs), due to the advantages of high image quality, power saving, thinness and wide application range, are widely applied to various consumer electronic products, such as, mobile phones, televisions, personal digital assistants (PDA), digital cameras, notebook computers, and desktop computers, and have become mainstream in display devices.

Most of the existing LCD devices are backlight type LCD displays, which include an LCD panel and a backlight module.

The power management circuit of the LCD device supplies various voltages, such as, an analog voltage AVDD, a gate-on voltage VGH, a gate-off voltage VGL, and a common electrode voltage VCOM to drive an LCD device for display images.

At present, the size of the LCD panel is getting larger and larger, and the voltage and current required by the LCD panel are getting larger and larger. Therefore, the capacitance used for each voltage is also large, and the requirement for the input voltage VIN is also increasingly higher, such as, an accurate range of input voltage VIN, small voltage drop under different loads, appropriate rising speed, and so on.

The current power management circuit (PMIC) does not have a design to detect the rising speed of the input voltage VIN. In fact, if the rising speed is very fast, it may cause a large surge current. If the rising speed is slow, it may cause the system to be in a low-voltage operating state when turned on. Both of these conditions may cause damage to the panel drive, causing major problems, such as, damage to the fuse and damage to the back-end chip (IC). and many more.

### SUMMARY OF THE INVENTION

The object of the present invention is to provide a circuit for detecting the input voltage rising speed, able to detect the rising speed of the input voltage inside the power management circuit.

Another object of the present invention is to provide a method for detecting the input voltage rising speed, able to detect the rising speed of the input voltage inside the power management circuit.

To achieve the above object, the present invention provides a circuit for detecting input voltage rising speed, comprising:

a voltage dividing circuit for dividing an input voltage to provide a first voltage;

a charging circuit comprising a capacitor, a switch and a current source, the current source being connected to an input end of the switch, an output end of the switch being connected to a first end of the capacitor, a second end of the capacitor being grounded, a control end of the switch being connected to an output end of a first comparator, the first end of the capacitor providing a second voltage;

a first comparator, configured to compare the first voltage with a first reference voltage, and output a comparison result to be used to control the switch;

a second comparator, configured to compare the second voltage and a fourth reference voltage, and output a first result;

a third comparator, configured to compare the second voltage and a third reference voltage, and output a second result;

a fourth comparator, configured to compare the first voltage and a second reference voltage, and output a third result, where the third result being an enable signal of a logic determiner; when the first voltage being greater than the second reference voltage, the third result enabling the logic determiner;

a logic determiner, configured to receive the first result, the second result and the third result, and determine, according to the third result, whether a logical determination being needed, and when the logic determination being needed, an input voltage rising speed being determined according to a preset logic, the first result, and the second result, and a fourth result being outputted;

wherein the third reference voltage being greater than the fourth reference voltage, and the second reference voltage being greater than the first reference voltage.

Wherein the logic determiner determines the input voltage rising speed according to the preset logic, the first result, and the second result, and the outputting of the fourth result comprises:

if the second voltage is less than the fourth reference voltage and less than the third reference voltage, the logic determiner determines that the input voltage rises too fast;

if the second voltage is greater than the fourth reference voltage and less than the third reference voltage, the logic determiner determines that the input voltage rise speed is normal;

if the second voltage is greater than the fourth reference voltage and greater than the third reference voltage, the logic determiner determines that the input voltage rise speed is too slow.

Wherein, the logic determiner sends the fourth result to a system-on-chip, and the system-on-chip controls an AC/DC conversion circuit to generate the rising speed of the input voltage according to the fourth result.

Wherein, when the first voltage is greater than the first reference voltage, the comparison result output by the first comparator controls the switch to be closed.

Wherein, the voltage dividing circuit comprises a first resistor and a second resistor, a first end of the first resistor is connected to the input voltage, and a second end of the first resistor is connected to a first end of the second resistor and provides a first voltage, a second end of the second resistor is grounded.

Wherein, the switch is a triode or a metal oxide semiconductor (MOS) transistor.

Wherein, a non-inverting input terminal of the first comparator inputs the first voltage, and an inverting input terminal inputs the first reference voltage;

a non-inverting input terminal of the second comparator inputs a second voltage, and an inverting input terminal inputs the fourth reference voltage;

a non-inverting input terminal of the third comparator inputs the second voltage, and an inverting input terminal inputs the third reference voltage;

a non-inverting input of the fourth comparator inputs the first voltage, and an inverting input inputs the second reference voltage.

The invention also provides a method for detecting input voltage rising speed, applicable to the circuit for detecting input voltage rising speed according to any of the above embodiments, comprising:

the voltage dividing circuit dividing the input voltage to provide a first voltage;

in the charging circuit, the switch controlling whether the current source charging the capacitor, and the first end of the capacitor providing the second voltage;

the first comparator comparing the first voltage with the first reference voltage, and the output comparison result being used to control the switch;

the second comparator comparing the second voltage and the fourth reference voltage to output a first result;

the third comparator comparing the second voltage and the third reference voltage to output a second result;

the fourth comparator comparing the first voltage and the second reference voltage to output a third result;

the logic determiner receiving the first result, the second result, and the third result, and determining whether a logic determination being needed according to the third result, and when the logic determination being needed, determining the input voltage rising speed according to the preset logic, the first result, and the second result, outputting a fourth result;

wherein the third reference voltage being greater than the fourth reference voltage, and the second reference voltage being greater than the first reference voltage.

Wherein, the logic determiner determining whether a logic determination being needed according to the third result comprises when the first voltage is greater than the second reference voltage, the logic determiner determines that a logical determination is needed according to the third result.

Wherein the logic determiner determines the input voltage rising speed according to the preset logic, the first result, and the second result, and the outputting of the fourth result comprises:

if the second voltage is less than the fourth reference voltage and less than the third reference voltage, determining that the input voltage rises too fast;

if the second voltage is greater than the fourth reference voltage and less than the third reference voltage, determining that the input voltage rise speed is normal;

if the second voltage is greater than the fourth reference voltage and greater than the third reference voltage, determining that the input voltage rise speed is too slow.

In summary, the circuit and method for detecting input voltage rising speed of the present invention can detect the rising speed of the input voltage inside the power management circuit. By adopting the invention, if the rising speed of the power-on input voltage is greater than or less than a preset required value, it is determined that an abnormality has occurred, and a feedback message of abnormality can be used to notify to avoid working in an abnormal state.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the principle of the circuit for detecting input voltage rising speed of the present invention;

FIG. 2 is a schematic view showing an application scenario block diagram of a preferred embodiment of the circuit for detecting input voltage rising speed of the present invention.

### DETAILED DESCRIPTION OF THE PREFERRED EMBODIMENTS

To further explain the technical means and effect of the present invention, the following refers to embodiments and drawings for detailed description.

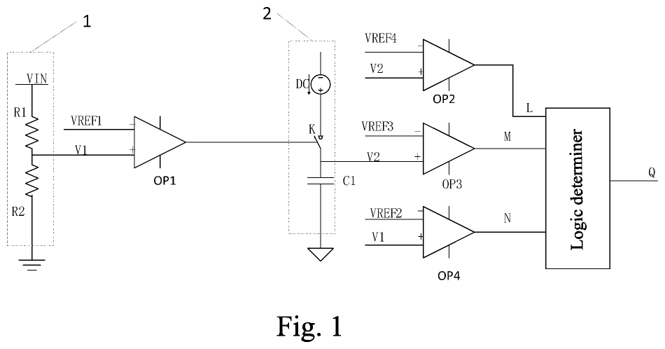

Refer to FIG. 1. FIG. 1 is a schematic view showing the principle of the circuit for detecting input voltage rising speed of the present invention. The circuit for detecting input voltage rising speed mainly comprises: a voltage dividing circuit 1, a charging circuit 2 comprising of a capacitor C1, a switch K and a direct current (DC) current source, first to fourth comparators OP1 to OP4, and a logic determiner. The circuit shown in FIG. 1 is only for exemplifying the present invention, and various other changes and modifications can be made by those skilled in the art in light of the technical solutions and technical concept of the present invention.

In FIG. 1, the voltage dividing circuit 1 is used to divide the input voltage VIN to provide a first voltage V1. The voltage dividing circuit 1 may specifically comprise a first resistor R1 and a second resistor R2. The first end of the first resistor R1 is connected to the input voltage, the second end of the first resistor R1 is connected to the first end of the second resistor R2 and provides a first voltage V1, and the second end of the second resistor R2 is grounded. That is, the first voltage V1 is collected from a connection point between the first resistor R1 and the second resistor R2, thereby sampling the input voltage VIN.

The charging circuit 2 comprises a switch K, a capacitor C1 and a current source. The direct current (DC) current source is controlled by the switch K to charge the capacitor C1. The second end of the capacitor C1 is grounded, and the first end is connected to the output end of the switch K, and the input end of the switch K is connected to the current source, and the other end of the capacitor C1 provides a second voltage V2; the switch K can be a triode or a MOS transistor, or other suitable switching components.

The first comparator OP1 is configured to compare the first voltage V1 with a first reference voltage VREF1, and the outputted comparison result is used to control the switch K of the charging circuit 2. In the preferred embodiment, the condition is set as follows: when the first voltage V1 is greater than a reference voltage VREF1, the first comparator OP1 controls the switch K of the charging circuit 2 to be closed, and the current source charges the capacitor C1; the first reference voltage VREF1 is a starting point for begin to detect the rising speed of the input voltage VIN;

the second comparator OP2 is used to compare the second voltage V2 and a fourth reference voltage VREF4, and output a first result L;

the third comparator OP3 is used to compare the second voltage V2 and a third reference voltage VREF3, and output a second result M;

the fourth comparator OP4 is configured to compare the first voltage V1 and a second reference voltage VREF2 to output a third result N, and the third result N is an enable signal of the logic determiner; when the first voltage V1 is greater than the second reference voltage VREF2, the third result N enables the logic determiner; the second reference voltage VREF2 is an end point for calculating the rise time of the input voltage VIN;

wherein the third reference voltage VREF3 is greater than the fourth reference voltage VREF4, and the second reference voltage VREF2 is greater than the first reference voltage VREF1. The present invention detects the rising speed of the input voltage VIN by setting four reference voltages; in this embodiment, the four reference voltages are respectively inputted to the inverting input terminals of the corresponding comparators.

The present invention pre-sets the current source and the capacitor C1, and the second voltage V2 on the capacitor C1 after charging is time-dependent. By comparing the second voltage V2 with the preset third reference voltage VREF3 and the preset fourth reference voltage VREF4, respectively, the time rise interval of the input voltage VIN is used as a reference for comparing the rising speed.

The invention first divides the input voltage VIN to obtain the first voltage V1, which is first compared with the first reference voltage VREF1, which is the starting point voltage for begin to detect the rising speed of the input voltage VIN. When the first voltage V1 begins to be greater than the first reference voltage VREF1, the first comparator OP1 can output a high voltage, and the switch K of the charging circuit 2 is controlled to charge the capacitor C1. The charging time and result of the capacitor C1 are determined by the second comparator OP2 and the third comparator OP3, and the second reference voltage VREF2 is the end point for calculating the rise time of the input voltage VIN.

In the present invention, the input voltage VIN rises with time, and the first voltage V1 obtained by dividing the input voltage VIN also rises with time. By respectively dividing the first voltage V1 compared with the preset first reference voltage VREF1 and the second reference voltage VREF2, the voltage rise interval of the input voltage VIN is set in advance as a reference for comparing the rising speed.

The logic determiner is configured to receive the first result L, the second result M, and the third result N, and determine whether a logical determination is needed according to the third result N. When it is determined that the logic determination is needed, the input voltage rising speed is determined according to the preset logic, the first result L and the second result M, and a fourth result Q is outputted. The logic determiner can be specifically implemented by using a logic circuit, a single chip, a CPU or an FPGA.

The logic determiner determines the input voltage rising speed according to the preset logic, the first result L and the second result M. The preset logic for determining the rising speed of the input voltage according to the present invention may comprise: if the second voltage V2 is smaller than the fourth reference voltage VREF4 and less than the third reference voltage VREF3, determining that the input voltage rise speed is too fast; if the second voltage V2 is greater than the fourth reference voltage VREF4 and less than the third reference voltage VREF3, determining that the input voltage rise speed is normal; if the second voltage V2 is greater than the fourth reference voltage VREF4 and greater than the third reference voltage VREF3, and determining that the input voltage rise speed is too slow.

In the preferred embodiment, the first result L, the second result M, and the third result N may be set to be represented by 0 or 1. In this case, the preset logic may specifically comprise: the third result N is the enable signal of the logic determiner, if the third result N is 1, the values of the first result L/second result M are read, and if the third result N is 0, the logic determiner is set to not operate; if the first result L/second result M are 0, the rising speed is proven to be too fast, and the time between the input voltage VIN rises from the first reference voltage VREF1 to the second reference voltage VREF2 is not sufficient; if the first result L is 1, the second result M is 0, the rising speed is within the preset specification, and the normal power-on can be performed; if the first result L/second result M are 1 at the same time, the rising speed is too slow and has exceeded the preset specification, which may cause problems and cause subsequent exceptions.

The invention can determine the rising speed of the input voltage VIN of the panel driving through the circuit, and can ensure the normal operation in the rising speed within the normal range by setting the normal range of the rising speed in advance, and if the rising speed is abnormal, the problem will be determined and the device can be set to not boot.

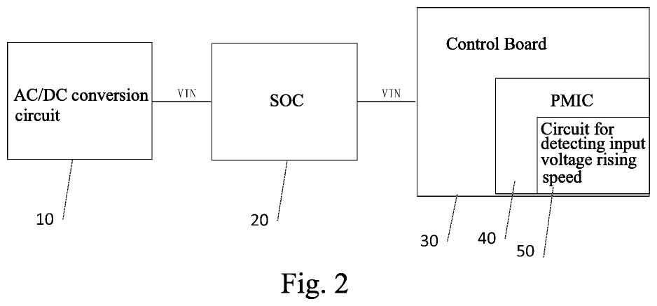

FIG. 2 is a schematic view showing an application scenario block diagram of a preferred embodiment of the circuit for detecting input voltage rising speed of the present invention. The alternating current/direct current (AC/DC) conversion circuit 10 generates an input voltage VIN, which is inputted to a system-on-chip (SOC) 20. The SOC 20 then inputs the input voltage VIN to the control board (CB) 30, and the circuit 50 for detecting input voltage rising speed of the present invention can be built into the power management circuit (PMIC) 40 on the control board 30 to detect the rising speed of the input voltage VIN. The circuit 50 for detecting the rising speed of the input voltage of the present invention can also be combined with the system segment to feed the fourth result Q outputted by the logic determiner to the SOC 20, and control the rising speed of the input voltage VIN by the AC/DC converting circuit 10.

In the circuit 50 for detecting the rising speed of the input voltage, the logic determiner determines the rising speed of the input voltage VIN according to the preset logic, the logic determiner outputs the fourth result Q, and inputs the fourth result Q into the SOC 20, and the SOC 20 controls the AC/DC conversion circuit 10 to generate a rising speed of the input voltage VIN and/or the SOC2—controls the power-on operation according to the fourth result Q: when the input voltage VIN rises too fast, the SOC 20 controls the AC/DC conversion circuit 10 to reduce the rising speed of the input voltage VIN; when the input voltage VIN rises at a normal speed, the SOC 20 controls the normal power-on; when the input voltage VIN rises too slowly, the SOC 20 controls the AC/DC conversion circuit 10 to increase the rising speed of the input voltage VIN.

The specific operation can be as follows: the fourth result Q is fed back to the SOC 20, and the fourth result Q is no longer is a form of 0/1, but becomes a voltage value, for example, 0/1.5/3.3V. If the output is 0V, the rising speed is proven to be too fast, the SOC 20 controls the AC/DC conversion circuit 10 to restart the input voltage VIN, and reduces the rising speed of the input voltage VIN. If the fourth result Q voltage is 3.3V, the input voltage VIN rises speed is too slow, the AC-DC conversion circuit 10 is controlled to increase the input voltage VIN rising speed. If the fourth result Q feedback level is 1.5V, the device is determined to be normally turned on.

The invention also provides a method for detecting input voltage rising speed, applicable to the circuit for detecting input voltage rising speed of the present invention, comprising:

the voltage dividing circuit 1 dividing the input voltage to provide a first voltage V1;

in the charging circuit 2, the switch K controlling whether the current source charging the capacitor C1, and the first end of the capacitor C1 providing the second voltage V2;

the first comparator OP1 comparing the first voltage V1 with the first reference voltage VREF1, and the output comparison result being used to control the switch K;

the second comparator OP2 comparing the second voltage V2 and the fourth reference voltage VREF4 to output a first result L;

the third comparator OP3 comparing the second voltage V2 and the third reference voltage VREF3 to output a second result M;

the fourth comparator OP4 comparing the first voltage V1 and the second reference voltage VREF2 to output a third result N; determining whether to perform a logic determination according to the third result N; when the first voltage V1 is greater than the second reference voltage VREF2, determining that the logic determination is performed according to the third result N;

the logic determiner receiving the first result L, the second result M, and the third result N, and determining whether a logic determination being needed according to the third result N, and when the logic determination being needed, determining the input voltage rising speed according to the preset logic, the first result L, and the second result M, outputting a fourth result Q;

wherein the third reference voltage VREF3 is greater than the fourth reference voltage VREF4, and the second reference voltage VREF2 is greater than the first reference voltage VREF1.

The logic determiner determining whether a logic determination being needed according to the third result N comprises when the first voltage V1 is greater than the second reference voltage VREF2, the logic determiner determines that a logical determination is needed according to the third result N.

The present invention sets in advance the time rise interval of the input voltage VIN as a reference for comparing the rising speed by comparing the second voltage V2 with the preset third reference voltage VREF3 and the preset fourth reference voltage VREF4, respectively. By comparing the first voltage V1 with the preset first reference voltage VREF1 and the second reference voltage VREF2, respectively, the voltage rising interval of the input voltage VIN is set in advance as a reference for comparing the rising speed.

Wherein the logic determiner determines the input voltage rising speed according to the preset logic, the first result L, and the second result M, and the outputting of the fourth result Q comprises:

if the second voltage V2 is less than the fourth reference voltage VREF4 and less than the third reference voltage VREF3, determining that the input voltage rises too fast; if the second voltage V2 is greater than the fourth reference voltage VREF4 and less than the third reference voltage VREF3, determining that the input voltage rise speed is normal; if the second voltage V2 is greater than the fourth reference voltage VREF4 and greater than the third reference voltage VREF3, determining that the input voltage rise speed is too slow.

In summary, the circuit and method for detecting input voltage rising speed of the present invention can detect the rising speed of the input voltage inside the power management circuit. By adopting the invention, if the rising speed of the power-on input voltage is greater than or less than a preset required value, it is determined that an abnormality has occurred, and a feedback message of abnormality can be used to notify to avoid working in an abnormal state.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A circuit for detecting input voltage rising speed, comprising:
a voltage dividing circuit for dividing an input voltage to provide a first voltage;
a charging circuit comprising a capacitor, a switch and a current source, the current source being connected to an input end of the switch, an output end of the switch being connected to a first end of the capacitor, a second end of the capacitor being grounded, a control end of the switch being connected to an output end of a first comparator, the first end of the capacitor providing a second voltage;
a first comparator, configured to compare the first voltage with a first reference voltage, and output a comparison result to be used to control the switch;
a second comparator, configured to compare the second voltage and a fourth reference voltage, and output a first result;
a third comparator, configured to compare the second voltage and a third reference voltage, and output a second result;
a fourth comparator, configured to compare the first voltage and a second reference voltage, and output a third result, where the third result being an enable signal of a logic determiner; when the first voltage being greater than the second reference voltage, the third result enabling the logic determiner;
a logic determiner, configured to receive the first result, the second result and the third result, and determine, according to the third result, whether a logical determination being needed, and when the logic determination being needed, an input voltage rising speed being determined according to a preset logic, the first result, and the second result, and a fourth result being outputted;
wherein the third reference voltage being greater than the fourth reference voltage, and the second reference voltage being greater than the first reference voltage.

2. The circuit for detecting input voltage rising speed as claimed in claim 1,
wherein the logic determiner determines the input voltage rising speed according to the preset logic, the first result, and the second result, and the outputting of the fourth result comprises:
if the second voltage is less than the fourth reference voltage and less than the third reference voltage, the logic determiner determines that the input voltage rises too fast;
if the second voltage is greater than the fourth reference voltage and less than the third reference voltage, the logic determiner determines that the input voltage rise speed is normal;
if the second voltage is greater than the fourth reference voltage and greater than the third reference voltage, the logic determiner determines that the input voltage rise speed is too slow.

3. The circuit for detecting input voltage rising speed as claimed in claim 1, wherein the logic determiner sends the fourth result to a system-on-chip, and the system-on-chip controls an AC/DC conversion circuit to generate the rising speed of the input voltage according to the fourth result.

4. The circuit for detecting input voltage rising speed as claimed in claim 1, wherein when the first voltage is greater than the first reference voltage, the comparison result output by the first comparator controls the switch to be closed.

5. The circuit for detecting input voltage rising speed as claimed in claim 1, wherein the voltage dividing circuit comprises a first resistor and a second resistor, a first end of the first resistor is connected to the input voltage, and a second end of the first resistor is connected to a first end of the second resistor and provides a first voltage, a second end of the second resistor is grounded.

6. The circuit for detecting input voltage rising speed as claimed in claim 1, wherein the switch is a triode or a metal oxide semiconductor (MOS) transistor.

7. The circuit for detecting input voltage rising speed as claimed in claim 1, wherein:
a non-inverting input terminal of the first comparator inputs the first voltage, and an inverting input terminal inputs the first reference voltage;
a non-inverting input terminal of the second comparator inputs a second voltage, and an inverting input terminal inputs the fourth reference voltage;
a non-inverting input terminal of the third comparator inputs the second voltage, and an inverting input terminal inputs the third reference voltage;
a non-inverting input of the fourth comparator inputs the first voltage, and an inverting input inputs the second reference voltage.

8. A method for detecting input voltage rising speed, applicable to a circuit for detecting input voltage rising speed, the circuit for detecting input voltage rising speed comprising:
a voltage dividing circuit for dividing an input voltage to provide a first voltage;
a charging circuit comprising a capacitor, a switch and a current source, the current source being connected to an input end of the switch, an output end of the switch being connected to a first end of the capacitor, a second end of the capacitor being grounded, a control end of the switch being connected to an output end of a first comparator, the first end of the capacitor providing a second voltage;
a first comparator, configured to compare the first voltage with a first reference voltage, and output a comparison result to be used to control the switch;
a second comparator, configured to compare the second voltage and a fourth reference voltage, and output a first result;
a third comparator, configured to compare the second voltage and a third reference voltage, and output a second result;
a fourth comparator, configured to compare the first voltage and a second reference voltage, and output a third result, where the third result being an enable signal of a logic determiner; when the first voltage being greater than the second reference voltage, the third result enabling the logic determiner;
a logic determiner, configured to receive the first result, the second result and the third result, and determine, according to the third result, whether a logical determination being needed, and when the logic determination being needed, an input voltage rising speed being determined according to a preset logic, the first result, and the second result, and a fourth result being outputted;
wherein the third reference voltage being greater than the fourth reference voltage, and the second reference voltage being greater than the first reference voltage;
the method comprising:
the voltage dividing circuit dividing the input voltage to provide a first voltage;
in the charging circuit, the switch controlling whether the current source charging the capacitor, and the first end of the capacitor providing the second voltage;
the first comparator comparing the first voltage with the first reference voltage, and the output comparison result being used to control the switch;
the second comparator comparing the second voltage and the fourth reference voltage to output a first result;
the third comparator comparing the second voltage and the third reference voltage to output a second result;
the fourth comparator comparing the first voltage and the second reference voltage to output a third result;
the logic determiner receiving the first result, the second result, and the third result, and determining whether a logic determination being needed according to the third result, and when the logic determination being needed, determining the input voltage rising speed according to the preset logic, the first result, and the second result, outputting a fourth result;
wherein the third reference voltage being greater than the fourth reference voltage, and the second reference voltage being greater than the first reference voltage.

9. The method for detecting input voltage rising speed as claimed in claim 8, wherein the logic determiner determining whether a logic determination being needed according to the third result comprises when the first voltage is greater than the second reference voltage, the logic determiner determines that a logical determination is needed according to the third result.

10. The method for detecting input voltage rising speed as claimed in claim 8, wherein the logic determiner determines the input voltage rising speed according to the preset logic, the first result, and the second result, and the outputting of the fourth result comprises:
if the second voltage is less than the fourth reference voltage and less than the third reference voltage, the logic determiner determines that the input voltage rises too fast;
if the second voltage is greater than the fourth reference voltage and less than the third reference voltage, the logic determiner determines that the input voltage rise speed is normal;
if the second voltage is greater than the fourth reference voltage and greater than the third reference voltage, the logic determiner determines that the input voltage rise speed is too slow.

11. The method for detecting input voltage rising speed as claimed in claim 8, wherein the logic determiner sends the fourth result to a system-on-chip, and the system-on-chip controls an AC/DC conversion circuit to generate the rising speed of the input voltage according to the fourth result.

12. The method for detecting input voltage rising speed as claimed in claim 8, wherein when the first voltage is greater than the first reference voltage, the comparison result output by the first comparator controls the switch to be closed.

13. The method for detecting input voltage rising speed as claimed in claim 8, wherein the voltage dividing circuit comprises a first resistor and a second resistor, a first end of the first resistor is connected to the input voltage, and a second end of the first resistor is connected to a first end of the second resistor and provides a first voltage, a second end of the second resistor is grounded.

14. The method for detecting input voltage rising speed as claimed in claim 8, wherein the switch is a triode or a metal oxide semiconductor (MOS) transistor.

15. The method for detecting input voltage rising speed as claimed in claim 8, wherein:
a non-inverting input terminal of the first comparator inputs the first voltage, and an inverting input terminal inputs the first reference voltage;
a non-inverting input terminal of the second comparator inputs a second voltage, and an inverting input terminal inputs the fourth reference voltage;
a non-inverting input terminal of the third comparator inputs the second voltage, and an inverting input terminal inputs the third reference voltage;
a non-inverting input of the fourth comparator inputs the first voltage, and an inverting input inputs the second reference voltage.
